(19) United States
(12) Patent Application Publication
(10) Pub. No.: US 2006/0256623 A1
(43) Pub. Date: Nov. 16, 2006

(54) Partial string erase scheme in a flash memory device

(75) Inventor: Frankie F. Roohparvar, Monte Sereno, CA (US)

Correspondence Address: LEFFERT JAY & POLGLAZE, P.A.;Atth: Kenneth W. Bolvin, P.O. Box 581009, Minneapolis, MN, 55402, US

(73) Assignee: Micron Technology, Inc.

(21) Appl. No.: 11/127,619

(22) Filed: May 12, 2005

(51) Int. Cl. G11C 16/04

(52) U.S. Cl. 365/185.29

(57) ABSTRACT

A memory block has an increased quantity of memory cells while keeping the erase block the same size. The memory block is broken down into at least two memory sub-blocks. While one sub-block is biased with erase voltages, the other sub-block or shadow block is biased with erase inhibit voltages. For wear leveling purposes, the shadow block only experiences a predetermined quantity of program/erase cycles that is less than the maximum experienced by the normal memory sub-block.

### TECHNICAL FIELD OF THE INVENTION

The present invention relates generally to memory devices and in particular the present invention relates to erasing flash memory devices.

### BACKGROUND OF THE INVENTION

Memory devices are typically provided as internal, semiconductor, integrated circuits in computers or other electronic devices. There are many different types of memory including random-access memory (RAM), read only memory (ROM), dynamic random access memory (DRAM), synchronous dynamic random access memory (SDRAM), and flash memory.

A flash memory is a type of memory that can be erased and reprogrammed in blocks instead of one byte at a time. Each of the memory cells includes a floating gate field-effect transistor capable of holding a charge. Each of the cells can be electrically programmed on a random basis by charging the floating gate. The data in a cell is determined by the presence or absence of the charge in the floating gate. The charge can be removed from the floating gate by a block erase operation.

FIG. 1 illustrates a simplified schematic diagram of a NAND flash memory array. The memory array of FIG. 1, for purposes of clarity, does not show all of the elements typically required in a memory array. For example, only three bit lines are shown (BL1, BL2, and BL3) when the number of bit lines required actually depends upon the memory density. The bit lines are subsequently referred to as (BL1-BLN).

The array is comprised of an array of floating gate cells 101 arranged in series columns 103, 104, 105. Each of the floating gate cells 101 are coupled drain to source in each series chain 103, 104, 105. A word line (WL0-WL31) that spans across multiple series strings 103, 104, 105 is coupled to the control gates of every floating gate cell in a row in order to control their operation. The bit lines (BL1-BLN) are eventually coupled to sense amplifiers (not shown) that detect the state of each cell.

In operation, the word lines (WL0-WL31) select the individual floating gate memory cells in the series chain 103, 104, 105 to be written to or read from and operate the remaining floating gate memory cells in each series string 103, 104, 105 in a pass through mode. Each series string 103, 104, 105 of floating gate memory cells is coupled to a source line 106 by a source select gate 115, 116, 117 and to an individual bit line (BL1-BLN) by a drain select gate 111, 112, 113. The source select gates 115, 116, 117 are controlled by a source select gate control line SG(S) 118 coupled to their control gates. The drain select gates 111, 112, 113 are controlled by a drain select gate control line SG(D) 114.

The memory cells are usually grouped into memory blocks. A block is typically defined by the total number of bits per word line multiplied by the total number of cells per string. A block is further broken down into pages. A memory block is typically comprised of 64 pages.

During an erase operation, all of the cells of the memory block are erased at the same time by biasing the gates of the block being erased at 0V while the tub (i.e., portion of the substrate in which the cells are fabricated) and the source are biased at 20V. The electric field that is oriented with the minus side from the floating gate and the positive side from the body or substrate would attract the electrons off of the floating gate, thus erasing the cell. Typical prior art memory designs let the word lines of unselected blocks float so that coupling from the substrate charges up all of the unselected word lines to a higher value. The electric field across the floating gate and the substrate is not enough to erase the blocks.

The total physical size of a NAND string is dictated by the total size of the cells plus the overhead of the select transistors and corresponding contacts. The memory cells may be scaled to their minimum sizes but the select transistors are typically CMOS-type transistors and are much larger. For example, older memory devices had 16 cells per serial string with the same size and quantity of select transistors. In order to decrease the cost of memory, integrated circuit manufacturers went to 32 cells per serial string, thus decreasing the overhead per string. However, the size of the block was doubled so that the end user now has to erase twice as many cells at the same time. This could create problems for systems having software written for a predetermined number of cells. The additional erasing could also create erase stress on those cells not required to be erased.

For the reasons stated above, and for other reasons stated below which will become apparent to those skilled in the art upon reading and understanding the present specification, there is a need in the art for a flash memory device that has reduced overhead due to select transistors without increasing the erase stress associated with increased block sizes.

### SUMMARY

The above-mentioned problems with erasing a non-volatile memory device and other problems are addressed by the present invention and will be understood by reading and studying the following specification.

The present invention encompasses a method for erasing a memory device comprising a memory array. The memory array is comprised of a plurality of memory strings that are coupled to a source line and fabricated on a substrate. Each memory string is made up of at least two memory cell subsets. The method comprises biasing a first memory cell subset with erase voltages while a second memory cell subset is biased with erase inhibit voltages.

Further embodiments of the invention include methods and apparatus of varying

### BRIEF DESCRIPTION OF THE DRAWINGS

FIG. 1 shows a simplified schematic diagram of a typical prior art flash memory array.

FIG. 2 shows a simplified schematic diagram of one embodiment of a portion of the flash memory array of the present invention.

FIG. 3 shows a flowchart of one embodiment of the partial string erase scheme of the present invention.

FIG. 4 shows a flowchart of one embodiment of a method for memory cell wear leveling.

FIG. 5 shows a block diagram of one embodiment of an electronic system of the present invention.

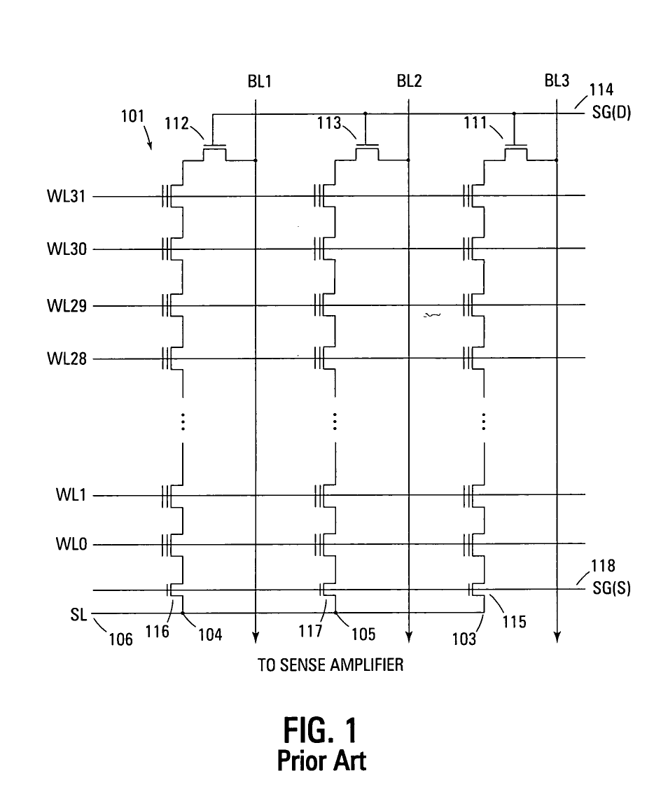

### DETAILED DESCRIPTION

In the following detailed description of the invention, reference is made to the accompanying drawings that form a part hereof and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined only by the appended claims and equivalents thereof.

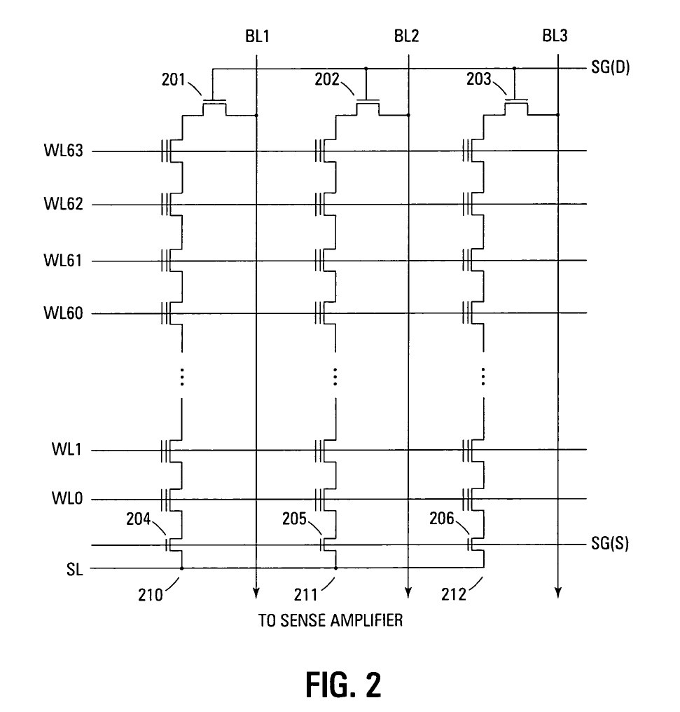

FIG. 2 illustrates a simplified schematic diagram of one embodiment of the memory block of the present invention. The present invention increases the quantity of the total memory cells in a string while maintaining the erasable memory block size. This is accomplished by creating two or more separately erasable subsets within the memory block. In one embodiment, a shadow block is created that is comprised of half of the memory cells in an increased size memory block. During an erase operation, only the normal memory block or its shadow block would be erased at any one time.

The embodiment of FIG. 2 illustrates an embodiment where the quantity of rows is increased to 64 (WL0-WL63). Doubling the quantity of rows is for purposes of illustration only. The present invention is not limited to any one increased quantity of rows.

By increasing the quantity of memory cells in each series string 210-212, the quantity of memory cells per select transistor 201-206 is thereby increased as well. This decreases the physical size of the required overhead for each string.

In the embodiment of FIG. 2, the first series string 210 is connected to the first bit line BL1 through a drain select transistor 201 and to the source line (SL) through a source select transistor 204. The second series string 211 is connected to the second bit line (BL2) through a second drain select transistor 202 and to the source line (SL) through a second source select transistor 205. Similarly, the third series string 212 is connected to the third bit line (BL3) through a third drain select transistor 203 and to the source line (SL) through a third source select transistor 206. The drain select transistors 201-203 are controlled by the select gate drain control line SG(D) while the source select transistors 204-206 are controlled by the select gate source control line SG(S).

For purposes of clarity, only three bit lines BL1-BL3 are shown in the embodiment of FIG. 2. However, it is well known in the art that a large quantity of bit lines would be used.

In one embodiment, the shadow block of the present invention is comprised of word lines 32-63 so that the “normal” memory block is comprised of word lines 0-31. Alternate embodiments may divide up the increased quantity of word lines in different ways. The quantity of rows in the normal memory block and the shadow memory block do not have to be equal.

One embodiment for an erase operation of the present invention biases the selected word lines of the memory block to be erased (e.g., normal memory block or shadow memory block) at 0V. The unselected word lines of the remaining memory block are biased at some high voltage (e.g., 20V) that would inhibit erase of those rows. The source line and the tub would be biased at 20V. Since both the normal and the shadow blocks share the same source and tub, both blocks would experience this biasing. The biasing of the memory blocks could then be switched in order to erase the block that was not erased previously.

During a program operation, the normal and shadow blocks are independent from each other except that the bit lines of the shadow block will be exercised whenever the other block is programmed. The same is true of the normal block when the shadow block is programmed. The embodiments of the present invention use a wear leveling scheme to track the number of times that each of these blocks are cycled between erase and program states. A lower quantity of cycles would then be allowed for the shadow block, in one embodiment. Thus, if a normal memory block is allowed to experience 10,000 erase/program cycles, the shadow block would only be allowed 5,000 cycles.

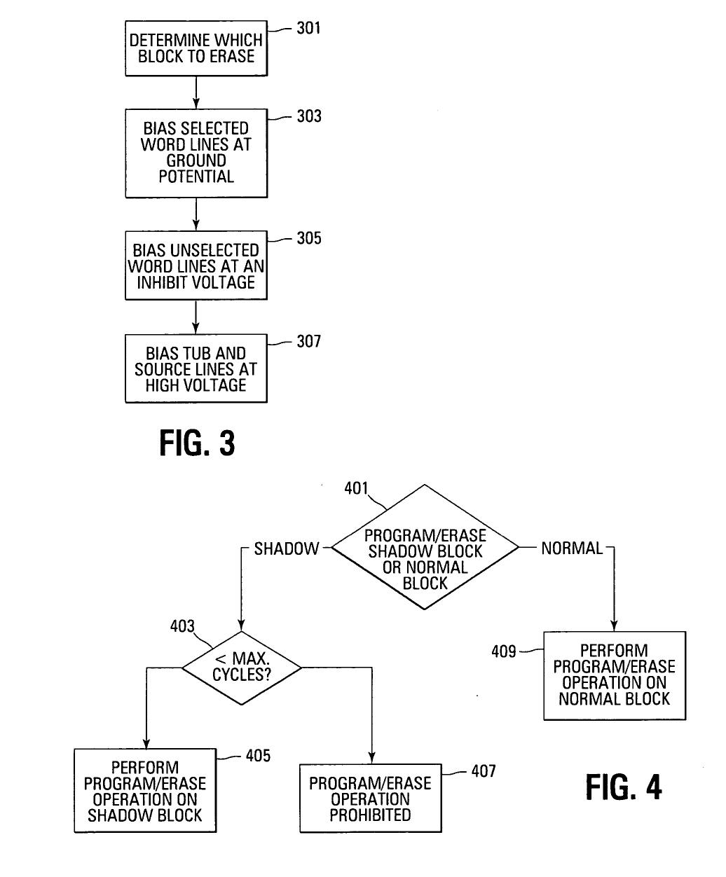

FIG. 3 illustrates a flowchart of one embodiment of a method for a partial string erase operation of the present invention. It is determined whether the shadow block or the normal block is to be erased 301. This determines how the word lines are to be biased.

The selected word lines are biased at ground potential 303. The unselected word lines are biased at some high inhibit voltage 305 that is greater than V_{CC} such as a voltage in the range of 16-20V. The source lines and tub are also biased at a high voltage 307. In one embodiment, this voltage is the same as the inhibit voltage. Alternate embodiments can use a voltage that is greater than V_{CC}.

In another embodiment, instead of biasing the unselected word lines at some high inhibit voltage, the unselected word lines can be left floating. Since the tub is biased at some high voltage, such as 20V, the floating word lines would be coupled up substantially close to that high tub voltage. This would perform the same inhibit function as in the bias voltage greater than V_{CC}.

In this alternate embodiment, there is the possibility that one or more of the unselected word lines nearest the selected word lines at ground potential might not have a high enough voltage to inhibit the erase operation. In such an embodiment, the word lines closest to the selected word lines could be biased at some high inhibit voltage as stated previously.

FIG. 4 illustrates a flowchart of one embodiment of a method for memory cell wear leveling. This method provides more even memory block cycling between the shadow block and the normal block due to the program or erase disturb condition.

It is determined whether the shadow block or the normal block is being programmed or erased 401. If the normal memory block is being programmed/erased, a normal program/erase operation is performed on the memory block 409.

If the shadow memory block is to be programmed/erased, the quantity of program/erase cycles is checked to determine if a maximum quantity of cycles have occurred 403. If the quantity of cycles is less than the maximum threshold, a normal program/erase operation is performed 405. If the maximum threshold has been reached or exceeded, the program/erase operation is prohibited 407.

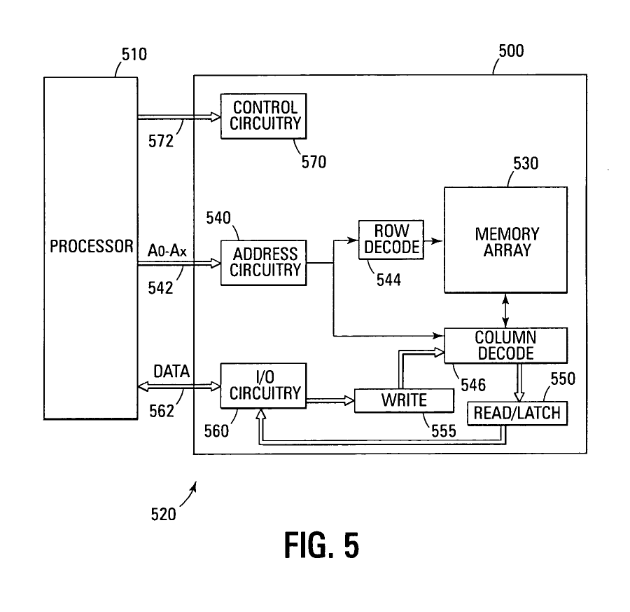

FIG. 5 illustrates a functional block diagram of a memory device 500 of one embodiment of the present invention that is coupled to a processor 510. The processor 510 may be a microprocessor, a processor, or some other type of controlling circuitry. The memory device 500 and the processor 510 form part of an electronic system 520. The memory device 500 has been simplified to focus on features of the memory that are helpful in understanding the present invention.

The memory device includes an array of memory cells 530. In one embodiment, the memory cells are non-volatile floating-gate memory cells and the memory array 530 is arranged in banks of rows and columns.

An address buffer circuit 540 is provided to latch address signals provided on address input connections A0-Ax 542. Address signals are received and decoded by a row decoder 544 and a column decoder 546 to access the memory array 530. It will be appreciated by those skilled in the art, with the benefit of the present description, that the number of address input connections depends on the density and architecture of the memory array 530. That is, the number of addresses increases with both increased memory cell counts and increased bank and block counts.

The above-described embodiments have focused on a NAND architecture memory array. However, the present invention is not limited to this architecture. The embodiments of the memory block erase method of the present invention can be used in any architecture of memory device (e.g., NAND, NOR, AND).

The memory device 500 reads data in the memory array 530 by sensing voltage or current changes in the memory array columns using sense/latch circuitry 550. The sense/latch circuitry, in one embodiment, is coupled to read and latch a row of data from the memory array 530. Data input and output buffer circuitry 560 is included for bidirectional data communication over a plurality of data connections 562 with the controller 510). Write circuitry 555 is provided to write data to the memory array.

Control circuitry 570 decodes signals provided on control connections 572 from the processor 510. These signals are used to control the operations on the memory array 530, including data read, data write, and erase operations. In one embodiment, the control circuitry 570 executes the embodiments of the partial string erase scheme of the present invention. The control circuitry 570 can also be responsible for preventing further program/erase cycles on the shadow memory once the program/erase cycle threshold has been reached. The control circuitry 570 may be a state machine, a sequencer, or some other type of controller.

The flash memory device illustrated in FIG. 5 has been simplified to facilitate a basic understanding of the features of the memory. A more detailed understanding of internal circuitry and functions of flash memories are known to those skilled in the art.

### CONCLUSION

In summary, the embodiments of the present invention increase the quantity of cells per string while keeping the erasable block the same size, thus reducing the total overhead of the select transistors. A partial string erase scheme is used during the erase operation to erase only a portion of the larger memory block, effectively reducing the larger memory block during an erase operation to a normal memory block and a shadow memory block. A wear leveling scheme reduces the impact of the block cycling on the shadow block.

Although specific embodiments have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

What is claimed is:

1. A method for erasing a memory device having a memory array comprising a plurality of memory strings coupled to a source line and fabricated on a substrate, the method comprising:
biasing with an erase voltage a first predetermined subset of a first memory string; and
biasing with an erase inhibit voltage a second predetermined subset of the first memory string.

2. The method of claim 1 wherein the memory array is a flash memory array.

3. The method of claim 1 wherein biasing with erase voltages comprises biasing selected word lines with a ground potential.

4. The method of claim 1 wherein biasing with inhibit voltages comprises biasing unselected word lines at a voltage greater than V_{CC}.

5. The method of claim 3 wherein biasing with erase voltage further comprises biasing the substrate and a source line coupled to the first memory string at a voltage greater than V_{CC}.

6. The method of claim 1 wherein the first memory string is comprised of 64 memory cells and the first and second predetermined subsets are each comprised of 32 memory cells.

7. The method of claim 1 and further comprising:
comparing a quantity of program/erase cycles performed on the second predetermined subset to a maximum threshold; and
inhibiting an erase operation on the second predetermined subset in response to the comparison.

8. The method of claim 7 wherein the erase operation to the second predetermined subset is inhibited when the quantity of program/erase cycles is greater than the maximum threshold.

9. A method for erasing a memory device having a memory array comprising a plurality of memory cell strings each coupled to a source line and fabricated on a substrate, each memory cell string comprising a first subset of memory cells and a second subset of memory cells, the method comprising:
determining a quantity of program/erase cycles performed on the second subset of memory cells;
preventing further erase operations on the second subset of memory cells if the quantity of program/erase cycles is greater than a predetermined threshold;
biasing the first subset of memory cells with erase voltages; and
biasing the second subset of memory cells with erase inhibit voltages.

10. The method of claim 9 and further including if the quantity of program/erase cycles is less than the predetermined threshold, biasing the first subset of memory cells with erase inhibit voltages and biasing the second subset of memory cells with erase voltages.

11. The method of claim 9 wherein the first and second subsets of memory cells are comprised of an equivalent quantity of memory cells.

12. The method of claim 9 wherein the predetermined threshold is five thousand program/erase cycles.

13. A memory device comprising:
a memory array comprising a plurality of memory cell strings each coupled to a source line and fabricated on a substrate, each memory cell string comprising a first subset of memory cells and a second subset of memory cells; and
memory control circuitry coupled to the memory array, the control circuitry adapted to control program and erase operations of the memory array such that only one of the first or the second subsets of memory cells of each memory cell string is biased for an erase operation at any one time.

14. The device of claim 13 wherein the memory control circuitry is further adapted to inhibit the second subset of memory cells while the first subset is biased for the erase operation.

15. The device of claim 13 wherein the memory control circuitry is further adapted to execute a wear leveling method such that the second subset of memory cells can only experience a predetermined quantity of program/erase cycles that is less than a maximum quantity of program/erase cycles experienced by the first subset of memory cells.

16. The device of claim 14 wherein the memory control circuitry is further adapted to bias unselected word lines of the second subset of memory cells at a voltage that inhibits an erase operation.

17. A memory device comprising:
a memory array comprising a plurality of memory blocks each having a source line and fabricated on a substrate, each memory block comprising a first subset memory block and a second subset memory block; and
memory control circuitry coupled to the memory array, the control circuitry adapted to control program and erase operations of the memory array such that only one of the first subset memory block or the second subset memory block is biased for an erase operation at any one time.

18. The device of claim 17 wherein the memory control circuitry erase inhibits one of the first or the second subset memory block while the remaining first or second subset memory block is being erased.

19. The device of claim 17 wherein the first subset memory block and the second subset memory block are comprised of an equivalent quantity of memory cells.

20. An electronic system comprising:
a processor that generates memory signals; and
a flash memory device, coupled to the processor, that operates in response to the memory signals, the device comprising:
a memory array comprising a plurality of memory cell strings each coupled to a source line and fabricated on a substrate, each memory cell string comprising a first subset of memory cells and a second subset of memory cells; and
memory control circuitry coupled to the memory array, the control circuitry adapted to control program and erase operations of the memory array such that only the first subset of memory cells of each memory cell string is biased for an erase operation.

21. The system of claim 20 wherein the processor is a state machine.

22. The system of claim 20 wherein the flash memory device is a NAND type flash memory device.

23. A method for erasing a memory device having a memory array comprising a plurality of memory cell strings each coupled to a source line and fabricated on a substrate, each memory cell string comprising a first subset of memory cells and a second subset of memory cells, each subset having 32 memory cells, the method comprising:
determining a quantity of program/erase cycles performed on the second subset of memory cells;
preventing further erase operations on the second subset of memory cells if the quantity of program/erase cycles is greater than a predetermined threshold;
biasing selected word lines of the first subset of memory cells at ground potential and the substrate and source line at a voltage greater than V_{CC}; and
biasing unselected word lines of the second subset of memory cells at a voltage greater than V_{CC}.

24. The method of claim 23 wherein each memory cell string is comprised of 64 memory cells, a select drain transistor, and a select source transistor coupled to the source line.

25. A method for erasing a memory device having a memory array comprising a plurality of memory strings coupled to a source line and fabricated on a substrate, the method comprising:
biasing the substrate and a source line coupled to a first memory string at a voltage greater than V_{CC};
biasing, with an erase voltage, selected word lines of the first memory string; and
floating unselected word lines of the first memory string.

26. The method of claim 25 and further including if one or more of the unselected word lines are not at an erase inhibit voltage, biasing the unselected word lines not at an erase inhibit voltage with an inhibit voltage greater than Vcc.

27. The method of claim 26 wherein the one or more unselected word lines are substantially adjacent to at least one of the selected word lines.

28. The method of claim 25 wherein biasing the substrate and the source line includes biasing the substrate and the source line at 20V.
